(19) United States
(12) Patent Application Publication
(10) Pub. No.: US 2025/0125313 A1
(43) Pub. Date: Apr. 17, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: I-Tang LIU, Taichung City (TW); Hsiang-Hua HUANG, Taichung City (TW); Yu-Min LO, Taichung City (TW)

(21) Appl. No.: 18/807,473

(22) Filed: Aug. 16, 2024

(30) Foreign Application Priority Data
Oct. 12, 2023 (TW) 112138986

(51) Int. Cl. H01L 25/065; H01L 23/00; H01L 23/31; H01L 23/498; H01L 25/18

(52) U.S. Cl. CPC H01L 25/0657; H01L 23/3121; H01L 23/49811; H01L 24/16; H01L 24/24; H01L 24/73; H01L 25/18; H01L 2224/16227; H01L 2224/24226; H01L 2224/73207; H01L 2924/351

(57) ABSTRACT

An electronic package is provided and includes a first circuit structure having opposite first and second surfaces; an electronic component set including a first electronic component and a second electronic component and having opposite first and second sides, wherein the first electronic component is located on the first side and has opposite first active surface and first inactive surface, the second electronic component has opposite second active surface and second inactive surface, and a part of the second active surface protrudes and is exposed from an outside of the first electronic component to electrically connect to the first surface; and an encapsulating layer defining opposite first encapsulating surface and second encapsulating surface, wherein the second encapsulating surface is connected to the first surface. As such, the overall height of the electronic package can be reduced and the heat dissipation efficiency of the electronic package can be improved also.

### CROSS-REFERENCE TO RELATED APPLICATIONS

The present application is based upon and claims the right of priority to TW patent application Ser. No. 11/213,8986, filed Oct. 12, 2023, the disclosure of which is hereby incorporated by reference herein in its entirety for all purposes.

### BACKGROUND

### 1. Technical Field

The present disclosure relates to a semiconductor device, and more particularly, to an electronic package with a plurality of stacked electronic components and a manufacturing method thereof.

### 2. Description of Related Art

In recent years, due to the vigorous development of portable electronic products, various related products have also shown a trend of development towards high density, high performance and lightness, thinness, shortness and smallness. In order to meet this trend, the semiconductor industry has also developed various aspects of packaging that integrate multiple functions in order to meet the requirements of thin, light, compact and high-density of electronic products. While with the evolution of science and technology, semiconductor products and technologies have begun to move towards heterogeneous integration. To this end, three-dimensional multi-chip packaging structures and technologies have gradually arisen.

However, as shown in FIG. 1, in the structure of a conventional semiconductor package 1, a plurality of chips 101, 102, 103 are stacked on a circuit structure 110, wherein the electrical connections between the chips 102, 103 located on the upper layer and the circuit structure 110 on the bottom side and between those chips are made through conductive wires such as gold wires 104. However, because the encapsulating layer 120 must leave a space on its top to accommodate the gold wire 104, such that the volume of the semiconductor package 1 is hard to be reduced and cannot meet the development trend of today's electronic products. Moreover, the larger volume also causes that the heat generated internally during operation need to pass through a longer path before being conducted to the surface of the semiconductor package 1, thus resulting in poor heat dissipation efficiency.

Therefore, how to overcome the above-mentioned problems of the prior art has become an urgent issue to be solved.

### SUMMARY

In view of the aforementioned shortcomings of the prior art, the present disclosure provides an electronic package, which comprises: a first circuit structure having a first surface, a second surface opposite to the first surface, and at least a first circuit layer; an electronic component set having a first side and a second side opposite to the first side and including a first electronic component and a second electronic component, wherein the first electronic component is located on the first side and has a first active surface and a first inactive surface opposite to the first active surface, and the first electronic component is connected to the first surface of the first circuit structure via the first active surface and is electrically connected to the first surface via a plurality of first conductive elements, wherein the second electronic component has a second active surface and a second inactive surface opposite to the second active surface and is connected to the first inactive surface of the first electronic component via the second active surface, wherein a part of the second active surface protrudes and is exposed from an outside of the first electronic component, and the part of the second active surface that protrudes and is exposed from the first electronic component is electrically connected to the first surface via at least a second conductive element; and an encapsulating layer encapsulating the electronic component set and defined with a first encapsulating surface and a second encapsulating surface opposite to the first encapsulating surface, wherein the second encapsulating surface is connected to the first surface of the first circuit structure.

The present disclosure further provides a method of manufacturing an electronic package, the method comprises: providing a carrier board; disposing an electronic component set on the carrier board, wherein the electronic component set has a first side and a second side opposite to the first side and includes a first electronic component and a second electronic component, wherein the first electronic component is located on the first side and has a first active surface and a first inactive surface opposite to the first active surface, and the second electronic component has a second active surface and a second inactive surface opposite to the second active surface, wherein the first electronic component is stacked on the second active surface of the second electronic component via the first inactive surface, a part of the second active surface is exposed from the first electronic component, and the electronic component set is stacked on the carrier board via the second side; disposing a plurality of first conductive elements on the first active surface, and disposing at least a second conductive element on the part of the second active surface that protrudes and is exposed from the first electronic component; forming an encapsulating layer to encapsulate the electronic component set, wherein the encapsulating layer is defined with a first encapsulating surface and a second encapsulating surface opposite to the first encapsulating surface, the first encapsulating surface is connected to the carrier board, and an end of each of the first conductive elements and an end of the second conductive element that are not connected are exposed from the second encapsulating surface; forming a first circuit structure on the encapsulating layer, wherein the first circuit structure has a first surface and a second surface opposite to the first surface and includes at least a first circuit layer, wherein the first circuit structure is disposed on the first side of the electronic component set and the second encapsulating surface of the encapsulating layer via the first surface and is electrically connected to the first active surface and the second active surface via the first conductive elements and the second conductive element respectively; and removing the carrier board.

In the aforementioned electronic package and method, each of the first conductive elements is a conductive bump.

In the aforementioned electronic package and method, the second conductive element is a conductive bump or a conductive wire.

In the aforementioned electronic package and method, the second side of the electronic component set is coplanar with the first encapsulating surface.

In the aforementioned electronic package and method, the present disclosure further comprises forming a dielectric layer on the second side of the electronic component set and the first encapsulating surface.

In the aforementioned electronic package and method, the present disclosure further comprises forming a second circuit structure on the second side of the electronic component set and the first encapsulating surface.

In the aforementioned electronic package and method, the second circuit structure includes at least a redistribution layer.

In the aforementioned electronic package and method, the electronic component set further includes a third electronic component, and the third electronic component has a third active surface and a third inactive surface opposite to the third active surface and is connected to the second inactive surface of the second electronic component via the third active surface, wherein a part of the third active surface protrudes and is exposed from an outside of the second electronic component, and the part of the third active surface protruding and being exposed from the second electronic component is electrically connected to the second active surface and/or the first surface via at least a third conductive element.

In the aforementioned electronic package and method, the third conductive element is a conductive bump or a conductive wire.

It can be seen from the above, the electronic package and manufacturing method thereof of the present disclosure save space in the electronic package in the direction of its height by making the second active surface/the third active surface of the second electronic component/the third electronic component face toward the inside of the electronic package and be partially exposed during stacking the first electronic component with the second electronic component and/or the third electronic component, and then forming the second conductive element and/or the third conductive element between the parts of the second active surface/the third active surface that are exposed toward the inside of the electronic package and the first circuit structure respectively, so the height of the electronic package can be significantly reduced and the heat dissipation efficiency of the electronic package can be improved.

### BRIEF DESCRIPTION OF THE DRAWINGS

FIG. 1 is a schematic cross-sectional view of a conventional semiconductor package.

FIG. 2A to FIG. 2E-1 are schematic cross-sectional views of a first embodiment of the manufacturing method of an electronic package of the present disclosure.

FIG. 2E-2 is a schematic cross-sectional view of a variant aspect of the electronic package shown in FIG. 2E-1.

FIG. 2F is a schematic cross-sectional view of a variant aspect of the first embodiment of the electronic package of the present disclosure.

FIG. 2G is a schematic cross-sectional view of another variant aspect of the first embodiment of the electronic package of the present disclosure.

FIG. 3A to FIG. 3E are schematic cross-sectional views of a second embodiment of the manufacturing method of an electronic package of the present disclosure.

FIG. 3F is a schematic cross-sectional view of a variant aspect of the second embodiment of the electronic package of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “third,” “a,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

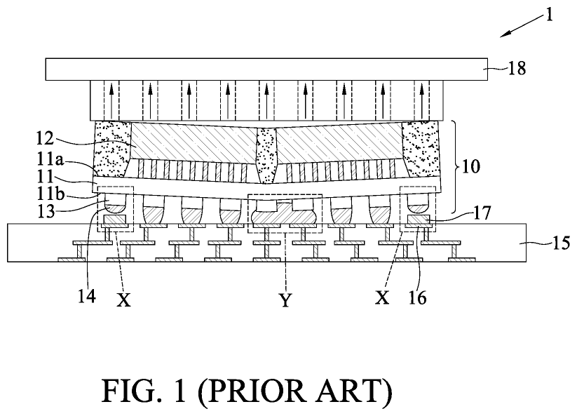

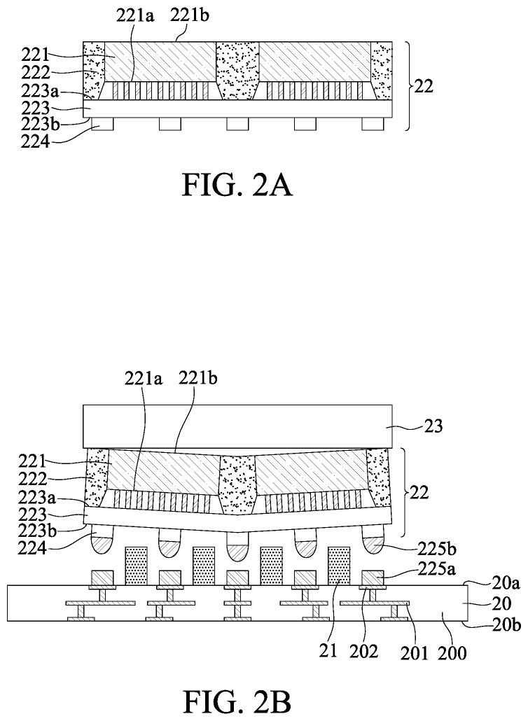

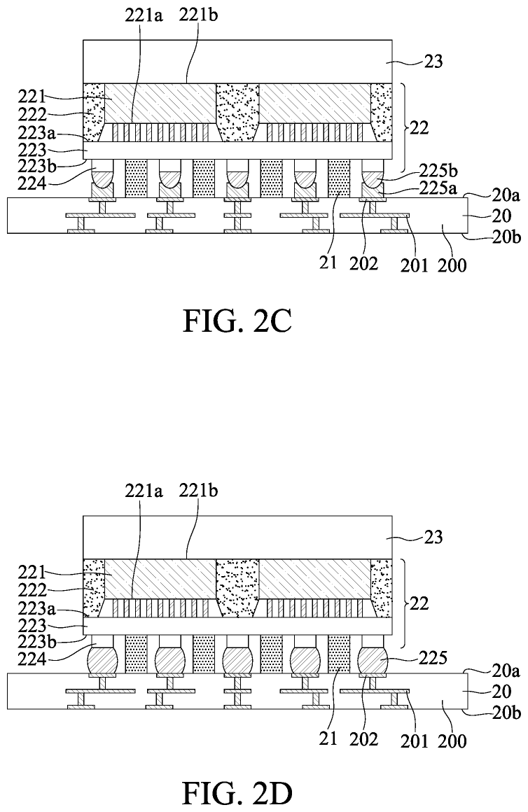

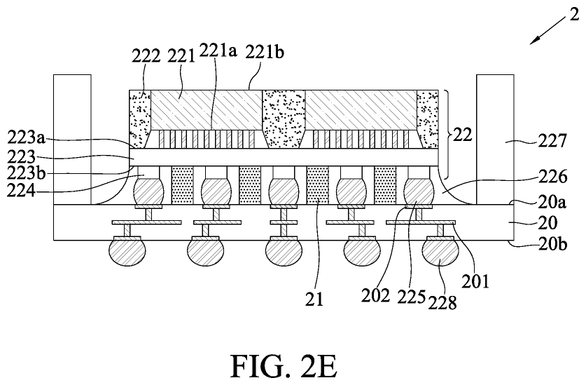

FIG. 2A to FIG. 2E-1 are schematic cross-sectional views of a first embodiment of the manufacturing method of an electronic package of the present disclosure.

As shown in FIG. 2A, a carrier board 70 is provided first. The carrier board 70 may be a plate body made of a semiconductor material (such as silicon or glass) or any other material that is suitable.

Next, an electronic component set 20 is disposed on the carrier board 70. The electronic component set 20 has a first side 20a and a second side 20b opposite to the first side 20a, and includes a first electronic component 21 and a second electronic component 22. The first electronic component 21 is located on the first side 20a of the electronic component set 20, and has a first active surface 21a and a first inactive surface 21b opposite to the first active surface 21a, and the location of the first active surface 21a is on the first side 20a of the electronic component set 20. The first electronic component 21 may be an active component (such as a semiconductor chip) or an inactive component (such as a resistor, a capacitor, or an inductor), while a semiconductor chip is used as an example in this embodiment.

The second electronic component 22 may also be an active component or an inactive component, and has a second active surface 22a and a second inactive surface 22b opposite to the second active surface 22a. The first inactive surface 21b of the first electronic component 21 is stacked on the second active surface 22a of the second electronic component 22 via an adhesive material such as a die attach film (DAF) 24; however, a part of the second active surface 22a is exposed. Since the electronic component set 20 in this embodiment includes only one first electronic component 21 and one second electronic component 22, the second inactive surface 22b of the second electronic component 22 is located on the second side 20b of the electronic component set 20 and is connected to the carrier board 70.

As shown in FIG. 2B, a plurality of first conductive elements 21c are disposed on the first active surface 21a of the first electronic component 21, and at least a second conductive element 22c is disposed on the part of the second active surface 22a of the second electronic component 22 that protrudes and is exposed from the side of the first electronic component 21. The plurality of first conductive elements 21c may be conductive bumps such as solder balls or copper bumps, and the second conductive element 22c is a conductive bump (such as a conductive pillar or a solder ball) or a conductive wire. In this embodiment, the first conductive elements 21c may be conductive bumps in the form of solder balls, while a conductive wire such as a gold wire that is electrically connected to the second active surface 22a by the wire bonding technics is used as an example of the second conductive element 22c.

As shown in FIG. 2C, the electronic component set 20 is encapsulated with an encapsulant or a molding compound such as a dry film or an epoxy so that an encapsulating layer 30 is formed, and the encapsulating layer 30 defines a first encapsulating surface 30a and a second encapsulating surface 30b opposite to the first encapsulating surface 30a. The first encapsulating surface 30a is corresponding to the second side 20b of the electronic component set 20 and is connected to the carrier board 70, and the second inactive surface 22b of the second electronic component 22 is coplanar with the first encapsulating surface 30a, and an end of each of the first conductive elements 21c and an end of the second conductive element 22c are made to be exposed from the second encapsulating surface 30b.

As shown in FIG. 2D, a first circuit structure 10 is formed on the encapsulating layer 30. The first circuit structure 10 defines a first surface 10a and a second surface 10b opposite to the first surface 10a, and includes at least a first circuit layer 11. The first circuit structure 10 is disposed on the first side 20a of the electronic component set 20 and the second encapsulating surface 30b of the encapsulating layer 30 via the first surface 10a, and is electrically connected to the first electronic component 21 and the second electronic component 22 via the first conductive elements 21c and the second conductive element 22c respectively.

As shown in FIG. 2E-1, the carrier board 70 is removed, then the electronic package 2 of this embodiment can be obtained.

FIG. 2E-2 is a schematic cross-sectional view of a variant aspect of the electronic package shown in FIG. 2E-1. The difference between the aspects shown in FIG. 2E-2 and FIG. 2E-1 is that a connection pad 22p is disposed on the surface of the second electronic component 22 in FIG. 2E-2 to connect to the second conductive element 22c made in the form of a conductive pillar via a solder ball 22s. In addition, an epoxy 31 may be filled between the first active surface 21a of the first electronic component 21 and the first circuit structure 10. The epoxy 31 is filled between the first active surface 21a of the first electronic component 21 and the first circuit structure 10 before formation of the encapsulating layer 30.

As shown in FIG. 2F, in a variant aspect, a dielectric layer 40 may be further formed on the second side 20b of the electronic component set 20 of the electronic package 2′, i.e., on the second inactive surface 22b of the second electronic component 22 and the first encapsulating surface 30a in this embodiment, and an adhesive layer 25 made of a material such as an epoxy may be formed on the second inactive surface 22b of the second electronic component 22 to connect the dielectric layer 40 as required. The material of the dielectric layer 40 may be a dielectric material such as polyimide (PI), but not limited to this.

In addition, as shown in FIG. 2G, in another variant aspect of embodiment, a second circuit structure 60 may further be disposed on the second side 20b of the electronic component set 20 of the electronic package 2″, i.e., on the second inactive surface 22b of the second electronic component 22 and the first encapsulating surface 30a in this embodiment, and an adhesive layer 25 made of a material such as an epoxy may be formed on the second inactive surface 22b of the second electronic component 22 to connect the second circuit structure 60 as required. The second circuit structure 60 includes a second circuit layer 61, and the second circuit layer 61 is a redistribution layer and may be electrically connected to the first circuit structure 10 via one or more fourth conductive elements 60c. Similarly, the fourth conductive element 60c may be a conductive wire (such as a gold wire) or a conductive bump (such as a conductive pillar), while conductive bumps in the form of conductive pillars are used as examples for both of the second conductive element 22c and the fourth conductive element 60c in the aspect shown in FIG. 2G, wherein a connection pad 22p is disposed on the surface of the second electronic component 22 to connect a conductive pillar used as the second conductive element 22c. Furthermore, in a variant aspect of embodiment, an epoxy 31 may be filled between the first active surface 21a of the first electronic component 21 and the first circuit structure 10. The epoxy 31 is filled between the first active surface 21a of the first electronic component 21 and the first circuit structure 10 before formation of the encapsulating layer 30.

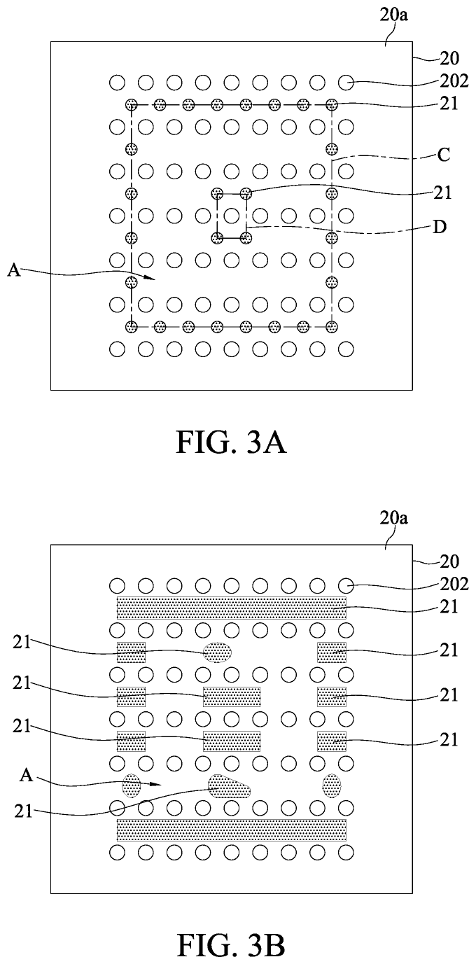

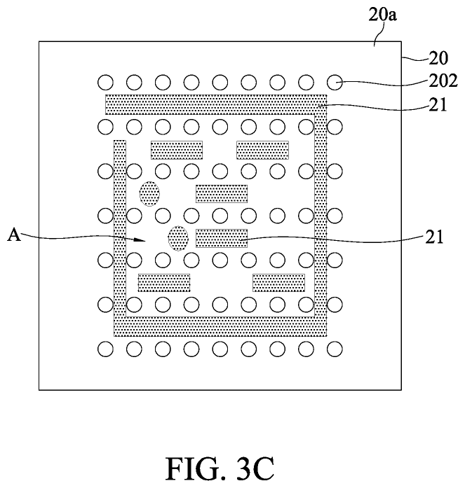

FIG. 3A to FIG. 3E are schematic cross-sectional views of a second embodiment of the manufacturing method of an electronic package of the present disclosure. The main difference between this embodiment and the aforementioned first embodiment is that the electronic component set 20′ of the electronic package 3 in this embodiment further includes a third electronic component 23 having a third active surface 23a and a third inactive surface 23b opposite to the third active surface 23a. The third electronic component 23 is connected to the second inactive surface 22b of the second electronic component 22 via the third active surface 23a thereof, and a part of the third active surface 23a of the third electronic component 23 protrudes and is exposed from an outside of the second electronic component 22. While the part of the third active surface 23a that protrudes and is exposed from the second electronic component 22 is electrically connected to the first surface 10a of the first circuit structure 10 and/or the second active surface 22a of the second electronic component 22 via at least a third conductive element 23c. It should be noted that the electrical connection between the third active surface 23a of the third electronic component 23 and the first surface 10a of the first circuit structure 10 may be a direct connection (such as through the conductive pillar shown in FIG. 2G) or an indirect electrical connection (e.g., as shown in FIG. 3E, the third active surface 23a of the third electronic component 23 is electrically connected to the second active surface 22a of the second electronic component 22 via the third conductive element 23c such as a gold wire first, and then the second active surface 22a of the second electronic component 22 is electrically connected to the first surface 10a of the first circuit structure 10 via the second conductive element 22c).

Since the third electronic component 23 is connected to the second inactive surface 22b of the second electronic component 22, in other words, the third electronic component 23 is located on the second side 20b′ of the electronic component set 20′ in this embodiment, and the third inactive surface 23b of the third electronic component 23 is also located on the second side 20b′ that is away from the first side 20a′ of the electronic component set 20′, so the surface connected to the carrier board 70 is the third inactive surface 23b of the third electronic component 23 as the electronic component set 20′ is being disposed on the carrier board 70. The surface that the first encapsulating surface 30a of the encapsulating layer 30 corresponding to is the third inactive surface 23b of the third electronic component 23 also.

Similar to the second conductive element 22c, the third conductive element 23c may also be a conductive bump or a conductive wire. While in this embodiment, it also uses a third conductive element 23c in the form of a conductive wire as an example.

Beside the parts that relate to the third electronic component 23 and/or the third conductive element 23c as aforementioned, the rest parts of the manufacturing method in this embodiment are the same as the method in the aforementioned first embodiment and therefore will not be explained repeatedly here.

In addition, FIG. 3F is a schematic cross-sectional view of a variant aspect of the second embodiment of the electronic package of the present disclosure. A second circuit structure 60 is further disposed on the second side 20b′ of the electronic component set 20′ of the electronic package 3′ provided by this aspect of embodiment, and a second circuit layer 61 (for instance, a redistribution layer) of the second circuit structure 60 may be electrically connected to the first circuit layer 11 in the first circuit structure 10 via one or more fourth conductive elements 60c. In this aspect of embodiment, the second conductive element 22c, the third conductive element 23c and the fourth conductive element 60c are all conductive pillars, also, the second conductive element 22c and the third conductive element 23c are electrically connected to the second electronic component 22 and the third electronic component 23 via a connection pad 22p disposed on the surface of the second electronic component 22 and a connection pad 23p disposed on the surface of the third electronic component 23 respectively. Basically, beside the third electronic component 23, the third conductive element 23c and the connection pad 23p, the structure of the electronic package 3′ shown in FIG. 3F is almost the same as the electronic package 2″ shown in FIG. 2G or at least is similar to it, therefore no repeated explanation will be made here.

This disclosure also shows an example of an electronic package 2. The electronic package 2 includes: a first circuit structure 10 having a first surface 10a, a second surface 10b opposite to the first surface 10a, and at least a first circuit layer 11; an electronic component set 20 having a first side 20a and a second side 20b opposite to the first side 20a and including a first electronic component 21 and a second electronic component 22, wherein the first electronic component 21 is located on the first side 20a and has a first active surface 21a and a first inactive surface 21b opposite to the first active surface 21a, and the first electronic component 21 is connected to the first surface 10a of the first circuit structure 10 via the first active surface 21a and is electrically connected to the first surface 10a via a plurality of first conductive elements 21c, wherein the second electronic component 22 has a second active surface 22a and a second inactive surface 22b opposite to the second active surface 22a and is connected to the first inactive surface 21b of the first electronic component 21 via the second active surface 22a, wherein a part of the second active surface 22a protrudes and is exposed from an outside of the first electronic component 21, and the part of the second active surface 22a that protrudes and is exposed from the first electronic component 21 is electrically connected to the first surface 10a via at least a second conductive element 22c; and an encapsulating layer 30 encapsulating the electronic component set 20 and defining a first encapsulating surface 30a and a second encapsulating surface 30b opposite to the first encapsulating surface 30a, wherein the second encapsulating surface 30b is connected to the first surface 10a of the first circuit structure 10.

In some aspects of the embodiment, each of the first conductive elements 21c is a conductive bump.

In some aspects of the embodiment, the second conductive element 22c is a conductive bump or a conductive wire.

In some aspects of the embodiment, the second side 20b of the electronic component set 20 is coplanar with the first encapsulating surface 30a.

In some aspects of the embodiment, a dielectric layer 40 is further formed on the second side 20b of the electronic component set 20 and the first encapsulating surface 30a.

In some aspects of the embodiment, a second circuit structure 60 is further formed on the second side 20b of the electronic component set 20 and the first encapsulating surface 30a.

In some aspects of the embodiment, the second circuit structure 60 includes at least a redistribution layer.

In another embodiment, the electronic component set 20′ further includes a third electronic component 23, wherein the third electronic component 23 has a third active surface 23a and a third inactive surface 23b opposite to the third active surface 23a and is connected to the second inactive surface 22b of the second electronic component 22 via the third active surface 23a, wherein a part of the third active surface 23a protrudes and is exposed from an outside of the second electronic component 22, and the part of the third active surface 23a that protrudes and is exposed from the second electronic component 22 is electrically connected to the second active surface 22a and/or the first surface 10a via at least a third conductive element 23c.

In some aspects of the embodiment, the third conductive element 23c is a conductive bump or a conductive wire.

In summary, the electronic package and manufacturing method thereof of the present disclosure save space in the electronic package in the direction of its height by making the second active surface/the third active surface of the second electronic component/the third electronic component face toward the inside of the electronic package and be partially exposed to form a stepped structure during stacking the first electronic component with the second electronic component and/or the third electronic component, and then forming the second conductive element and/or the third conductive element between the parts of the second active surface/the third active surface that are exposed toward the inside of the electronic package and the first circuit structure respectively, so the height of the electronic package can be significantly reduced. Also, since the height of the electronic package is reduced, the path for conducting the heat generated inside the electronic package during operation to the surface of the electronic package can be shortened, therefore the heat dissipation efficiency of the electronic package can be improved.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a first circuit structure having a first surface, a second surface opposite to the first surface, and at least a first circuit layer;
an electronic component set having a first side and a second side opposite to the first side and including a first electronic component and a second electronic component, wherein the first electronic component is located on the first side and has a first active surface and a first inactive surface opposite to the first active surface, and the first electronic component is connected to the first surface of the first circuit structure via the first active surface and is electrically connected to the first surface via a plurality of first conductive elements, wherein the second electronic component has a second active surface and a second inactive surface opposite to the second active surface and is connected to the first inactive surface of the first electronic component via the second active surface, wherein a part of the second active surface protrudes and is exposed from an outside of the first electronic component, and the part of the second active surface that protrudes and is exposed from the first electronic component is electrically connected to the first surface via at least a second conductive element; and
an encapsulating layer encapsulating the electronic component set and defined with a first encapsulating surface and a second encapsulating surface opposite to the first encapsulating surface, wherein the second encapsulating surface is connected to the first surface of the first circuit structure.

2. The electronic package of claim 1, wherein each of the first conductive elements is a conductive bump.

3. The electronic package of claim 1, wherein the second conductive element is a conductive bump or a conductive wire.

4. The electronic package of claim 1, wherein the second side of the electronic component set is coplanar with the first encapsulating surface.

5. The electronic package of claim 1, further comprising a dielectric layer formed on the second side of the electronic component set and the first encapsulating surface.

6. The electronic package of claim 1, further comprising a second circuit structure formed on the second side of the electronic component set and the first encapsulating surface.

7. The electronic package of claim 6, wherein the second circuit structure includes at least a redistribution layer.

8. The electronic package of claim 1, wherein the electronic component set further includes a third electronic component, and the third electronic component has a third active surface and a third inactive surface opposite to the third active surface and is connected to the second inactive surface of the second electronic component via the third active surface, wherein a part of the third active surface protrudes and is exposed from an outside of the second electronic component, and the part of the third active surface protruding and being exposed from the second electronic component is electrically connected to the second active surface and/or the first surface via at least a third conductive element.

9. The electronic package of claim 8, wherein the third conductive element is a conductive bump or a conductive wire.

10. A method of manufacturing an electronic package, comprising:
providing a carrier board;
disposing an electronic component set on the carrier board, wherein the electronic component set has a first side and a second side opposite to the first side and includes a first electronic component and a second electronic component, wherein the first electronic component is located on the first side and has a first active surface and a first inactive surface opposite to the first active surface, and the second electronic component has a second active surface and a second inactive surface opposite to the second active surface, wherein the first electronic component is stacked on the second active surface of the second electronic component via the first inactive surface, a part of the second active surface is exposed from the first electronic component, and the electronic component set is stacked on the carrier board via the second side;
disposing a plurality of first conductive elements on the first active surface, and disposing at least a second conductive element on the part of the second active surface that protrudes and is exposed from the first electronic component;
forming an encapsulating layer to encapsulate the electronic component set, wherein the encapsulating layer is defined with a first encapsulating surface and a second encapsulating surface opposite to the first encapsulating surface, the first encapsulating surface is connected to the carrier board, and an end of each of the first conductive elements and an end of the second conductive element are exposed from the second encapsulating surface;
forming a first circuit structure on the encapsulating layer, wherein the first circuit structure has a first surface and a second surface opposite to the first surface and includes at least a first circuit layer, wherein the first circuit structure is disposed on the first side of the electronic component set and the second encapsulating surface of the encapsulating layer via the first surface and is electrically connected to the first active surface and the second active surface via the first conductive elements and the second conductive element respectively; and
removing the carrier board.

11. The method of claim 10, wherein each of the first conductive elements is a conductive bump.

12. The method of claim 10, wherein the second conductive element is a conductive bump or a conductive wire.

13. The method of claim 10, wherein the second side of the electronic component set is coplanar with the first encapsulating surface.

14. The method of claim 10, further comprising forming a dielectric layer on the second side of the electronic component set and the first encapsulating surface.

15. The method of claim 10, further comprising forming a second circuit structure on the second side of the electronic component set and the first encapsulating surface.

16. The method of claim 15, wherein the second circuit structure includes at least a redistribution layer.

17. The method of claim 10, wherein the electronic component set further includes a third electronic component, and the third electronic component has a third active surface and a third inactive surface opposite to the third active surface and is connected to the second inactive surface of the second electronic component via the third active surface, wherein a part of the third active surface protrudes and is exposed from an outside of the second electronic component, and the part of the third active surface protruding and being exposed from the second electronic component is electrically connected to the second active surface and/or the first surface via at least a third conductive element.

18. The method of claim 17, wherein the third conductive element is a conductive bump or a conductive wire.
